(19) United States
(12) Patent Application Publication
(10) Pub. No.: US 2013/0044431 A1
(43) Pub. Date: Feb. 21, 2013

(54) LIQUID COOLING OF STACKED DIE THROUGH SUBSTRATE LAMINATION

(71) Applicant: Paul B. Koeneman, Palm Bay, FL (US)

(72) Inventor: Paul B. Koeneman, Palm Bay, FL (US)

(73) Assignee: HARRIS CORPORATION, Melbourne, FL (US)

(21) Appl. No.: 13/212,506

(22) Filed: Aug. 18, 2011

(51) Int. Cl. H05K 7/20; H05K 3/32

(52) U.S. Cl. 361/699; 29/832

(57) ABSTRACT

A liquid cooled package for integrated circuit dies includes flex circuit boards (10) that are laminated together, in which at least one of the circuit boards is dimensionally formed to create a cavity (19). Integrated circuit dies (20) are disposed within the cavity, each mounted to a respective circuit board. Fluidic pathways (33) are connected to the cavity and connect to an external fluid source (5). The integrated circuit dies abut each other within the cavity. Back surfaces (29) of the integrated circuit dies include grooves (22), and the abutting back surfaces form a stacked-die configuration with internal microchannels (23). The microchannels are preferably aligned with the fluidic pathways.

### BACKGROUND OF THE INVENTION

1. Statement of the Technical Field

The inventive arrangements relate to the packaging of integrated circuit dies, and more particularly to methods and related devices that provide for the liquid cooling of stacked dies.

2. Description of the Related Art

Signal latency between integrated circuits (ICs) is a major roadblock to increasing processing speeds. This, combined with the desire for miniaturization, is leading the drive for three dimensional (3D) stacking of IC dies. One major roadblock to 3D stacking, however, is thermal management for the ICs. Reduction of heat generation in ICs has not kept pace with size reductions for fabrication process generations. Consequently, heat fluxes in ICs are increasing with each generation and heat removal becomes increasingly important.

Given the problems associated with heat dissipation and removal in 3D die stacks, such packaging arrangements of dies have been limited to low power components, such as memory chips. Only recently has die stacking begun to be used in other applications, and in such cases liquid cooling is required. For single chip packages liquid cooling usually takes the form of separate cold plates with liquid channels. These cold plates abut the stacked dies and remove heat by way of conduction. However, cold plates introduce added complexity into the chip packaging process and increase the size of the final package.

### SUMMARY OF THE INVENTION

In one aspect a liquid cooled package for an integrated circuit die is disclosed. The package includes at least two circuit boards coupled together, in which at least one of the two circuit boards is dimensionally formed to form a first cavity. An integrated circuit die is disposed within the first cavity and is mounted on the circuit board. A plurality of first fluidic pathways are connected to the first cavity and configured for connecting to an external fluid source. In preferred embodiments the circuit boards are flex circuit boards that are laminated together and the fluidic pathways are provided by fluidic tubes that are sandwiched between the flex circuit boards. In some embodiments the first cavity comprises at least two integrated circuit dies that are mounted on respective circuit boards and abut each other within the cavity. In such embodiments it is preferred that back surfaces of the integrated circuit dies include grooves, and the abutting back surfaces form a stacked-die configuration with internal microchannels. The microchannels are preferably aligned with the first fluidic pathways.

In a specific embodiment electrical vias pass through one or both of the two circuit boards. Another dimensionally formed circuit board is coupled to the two circuit boards to form a second cavity, with at least another integrated circuit die disposed within the second cavity, and a plurality of second fluidic pathways are fluidically connected to the second cavity and configured for connecting to the external fluid source. The electrical via is aligned with, and electrically coupled to, a corresponding electrical via in the other dimensionally formed circuit board. In some embodiments, the other dimensionally formed circuit board is electrically and mechanically coupled to one of the two circuit boards using an electrically conductive adhesive.

In another aspect a packaging method for an integrated circuit is disclosed, in which at least two flex circuit boards are laminated together. At least one of the two flex circuit boards is a dimensionally formed circuit board so that a cavity with fluidic pathways is created when laminated to the other flex circuit board. An integrated circuit die is mounted on one of the flex circuit boards at a position such that it is disposed within the cavity. In some embodiments the method further includes forming a depression in a flex circuit board substrate to provide the dimensionally formed circuit board. In various embodiments fluidic tubes are interposed between the flex circuit boards prior to lamination so as to form the fluidic pathways. In a specific embodiment a respective integrated circuit die is mounted to each of the flex circuit boards and disposed within the cavity such that back surfaces of the integrated circuit dies abut each other within the cavity to form a stacked-die configuration. Preferably the back surfaces comprise grooves to form microchannels within the stacked-die configuration. In other embodiments the method further includes disposing an electrically conductive adhesive on at least one of the two flex circuit boards and then using the electrically conductive adhesive to mechanically and electrically couple to another flex circuit board.

### BRIEF DESCRIPTION OF THE DRAWINGS

Embodiments will be described with reference to the following drawing figures, in which like numerals represent like items throughout the figures, and in which:

FIG. 1. is a front cross-sectional view of an embodiment chip package.

FIG. 2 is a side cross-sectional view of an embodiment chip package.

FIG. 3 is a perspective view of a molding process for creating a dimensionally formed circuit board.

FIG. 4 is a detailed perspective view of a portion of a mold shown in FIG. 3.

FIG. 5 is a detailed perspective view of a finished dimensionally formed flex circuit board substrate.

FIG. 6 is a side view illustrating an embodiment method for creating a first packaging configuration.

FIG. 7 is a side view illustrating an embodiment method for creating a second packaging configuration.

FIG. 8 is a side view illustrating an embodiment method for creating a third packaging configuration.

FIG. 9 is a side view illustrating an embodiment method for creating a fourth packaging configuration.

FIG. 10 is a side cross-sectional view of an alternative embodiment of the chip package in FIG. 2.

FIG. 11 is an alternative embodiment of the invention which uses chip scale packaged integrated circuits.

### DETAILED DESCRIPTION

The invention is described with reference to the attached figures. The figures are not drawn to scale and they are provided merely to illustrate the instant invention. Several aspects of the invention are described below with reference to example applications for illustration. It should be understood that numerous specific details, relationships, and methods are set forth to provide a full understanding of the invention. One having ordinary skill in the relevant art, however, will readily recognize that the invention can be practiced without one or more of the specific details or with other methods. In other instances, well-known structures or operation are not shown in detail to avoid obscuring the invention. The invention is not limited by the illustrated ordering of acts or events, as some acts may occur in different orders and/or concurrently with other acts or events. Furthermore, not all illustrated acts or events are required to implement a methodology in accordance with the invention.

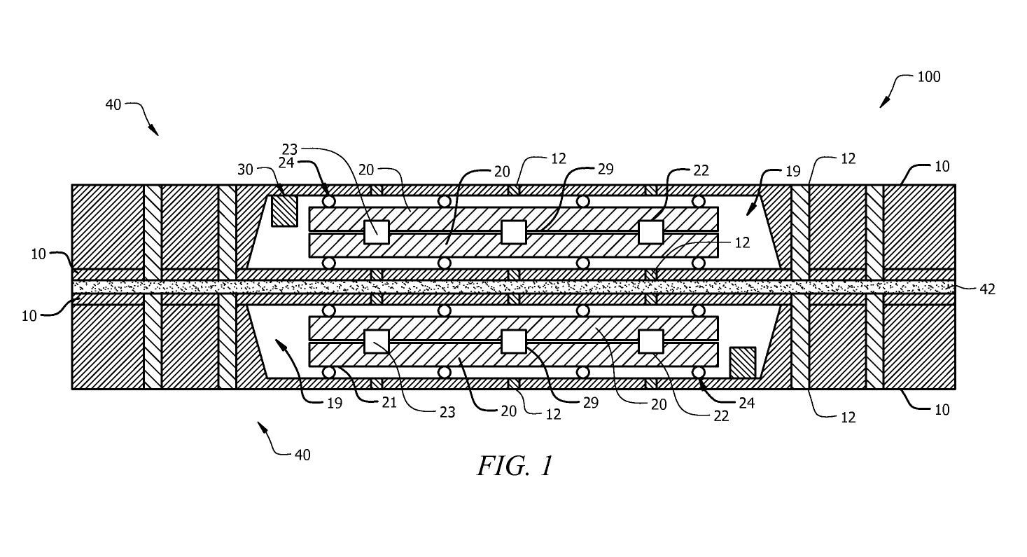

FIG. 1 is a front cross-sectional view of an embodiment chip package 100 having a stacked bare die configuration that employs liquid cooling. A bare die is an integrated circuit (IC) that has been cut out from a wafer and is ready for packaging. As shown in FIG. 1, the package 100 includes a plurality of bare IC dies 20, in a paired stacked configuration, with each bare die 20 mounted on a respective circuit board 10. The circuit boards 10 are preferably flex circuit boards, which can be made from liquid crystal polymer (LCP) substrates or the like, although any suitable circuit board may be employed. Flex circuit boards 10 are typically thin, such as about 25 microns thick, and thus preferred. LCP is preferred as it may be thermoformed to provide liquid seals, which is useful for the configurations discussed below. A front surface 21 of each die 20 is mechanically and electrically connected to its respective flex circuit board 10 by way of solder 24, adhesive, wire bonding or the like. Although only a single die 20 is shown coupled to each flex circuit board 10, it will be appreciated that each flex circuit board 10 can support more than a single die 20; a single die 20 is shown herein for convenience of description only. A back surface 29 of each die 20 is etched or otherwise processed so as to create a plurality of grooves or indentations 22. Pairs of dies 20 and flex circuit boards 10 are mounted together such that the adjacent back surfaces 29 of the dies 20 contact each other, with the grooves 22 aligned so as to create microchannels 23. The microchannels 23 are used to provide a fluidic pathway of coolant through the stacked die configuration, and may be of any suitable shape and size to support such fluidic pathways. For example, the grooves 22 can have a depth of from 20-400 microns and a width from 20-400 microns, to provide suitable corresponding microchannels 23.

The flex circuit boards 10 are configured so that when they are brought together a hermetic or near-hermetic cavity 19 can be formed for each pair of stacked dies 20. These cavities 19 can be provided by any suitable manufacturing process, such as by heating, molding, pressing or the like of the flex circuit boards 10. Vias 12 can also pass through each circuit board 10, and optionally be aligned with each other, so as to provide conductive pathways from one surface of a flex circuit board 10, such as a top surface, to another surface of a flex circuit board 10, such as a bottom surface, or to another circuit board 10 altogether. Because of the thin nature of the flex circuit board 10, such vias 12 can be very short and thus ensure a minimum of signal latency in the package 100. Additional supporting electrical components can also be mounted within the cavities 19. For example, coupling capacitors 30 and bonding wires (not shown) may be disposed within the cavities 19 and electrically and mechanically connected to a corresponding flex circuit board 10.

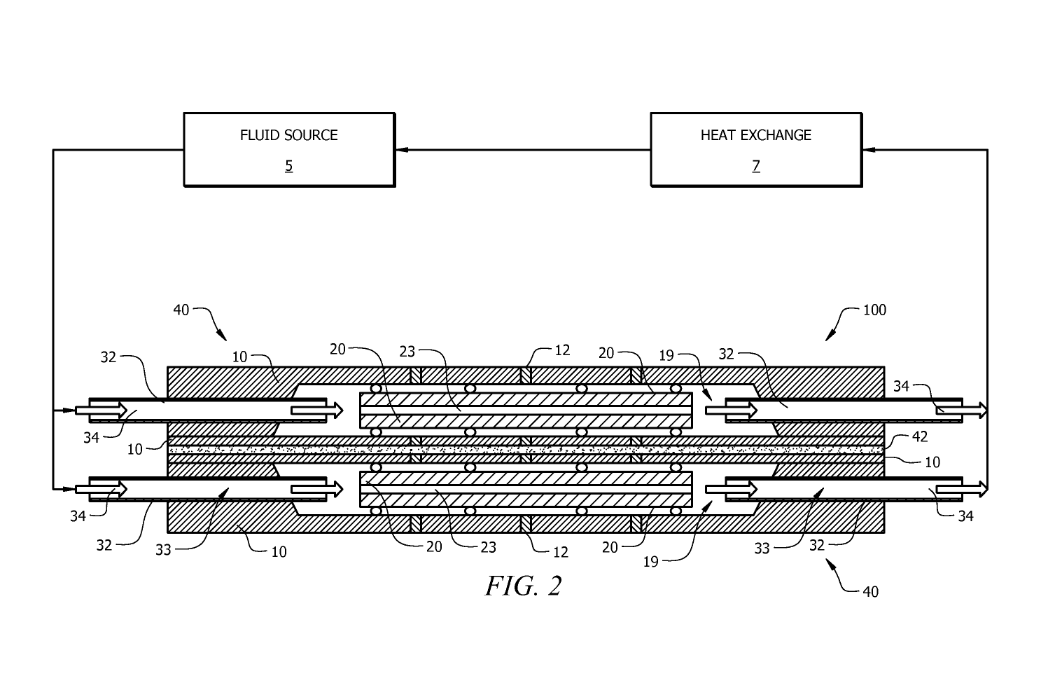

As indicated above, each flex circuit board 10 with its associated bare die(s) 20 is brought together with another flex circuit board 10 and its associated die(s) 20 to form a paired configuration 40, in which the adjacent back surfaces 29 of the dies 20 are paired together with their grooves 22 aligned to form a bare, stacked-die configuration with internal microchannels 23. As shown in FIG. 2, as part of each paired configuration 40, fluidic tubes 32 are disposed between the flex circuit boards 10. The fluidic tubes 32 provide fluidic pathways 33 that fluidically couple the cavity 19 with an external fluid source 5 to deliver fluid 34 into the cavity 19 at one end and that remove the fluid 34 from the cavity 19 at an opposite end. The external fluid source 5 can include a pump for circulating the fluid through the cavity. In an exemplary embodiment, the size range for the pathways 33 (tubes 32) is between 100 to 1000 microns. Fluid 34 can be any suitable coolant. For example, water can be used for this purpose provided that all electrical component conductive surfaces are coated with an insulating material. As an alternative, fluid 34 can be a dielectric liquid, such as Fluorinert™, which is commercially available from 3M™ Although discrete tubes 32 are used in a preferred embodiment, it will be appreciated that in other embodiments the fluidic pathways 33 may be provided, for example, simply by the appropriate shaping of one or more of the circuit boards 10.

As will be appreciated by those skilled in the art, fluid 34 circulating through the cavity 19 will absorb heat from the die(s) 20. In order to remove such heat from the fluid, a heat exchanger 7 is provided. The heat exchanger transfers heat from the fluid 34 to the surrounding environment. Heat exchangers are well known in the art and therefore will not be described here in detail. However, it should be understood that any suitable heat exchanger can be used for this purpose, provided that it is capable of transferring heat from the fluid 34 to the surrounding environment.

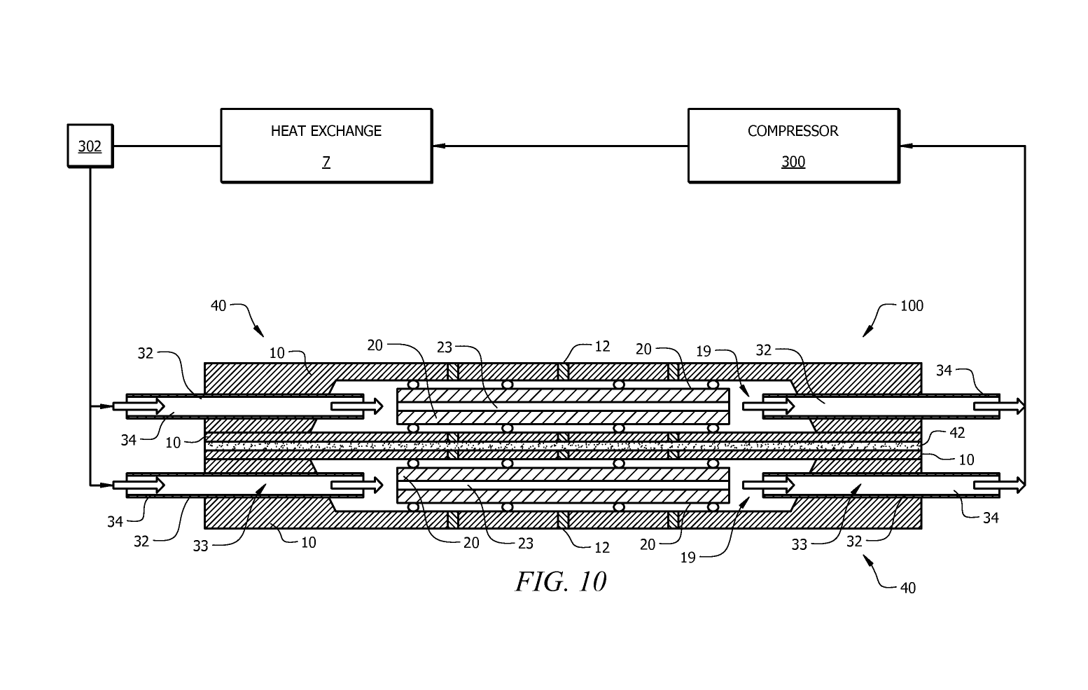

The embodiment shown in FIG. 2 can be used with single phase cooling or two phase cooling. In single phase cooling a fluid 34 remains in the same state (e.g. a liquid state) as it cycles from the heat source (i.e. the die 20) to the heat exchanger 7 and back to the heat source. In two phase cooling, the heat applied to the fluid by the die can cause the fluid to evaporate to a vaporous form. Subsequently, the vaporized fluid 34 can be condensed to a liquid form in the heat exchanger 7. Other embodiments are also possible. For example, a refrigeration cycle can be incorporated in the fluid cooling loop as shown in FIG. 10. In such an embodiment, a compressor 300 can compress the heated vaporous fluid prior to such fluid being communicated to heat exchanger 7. The heat exchanger removes heat from the compressed vapor and allows it to condense to a liquid. Thereafter, the fluid can be communicated to an expansion valve 302 which causes a pressure reduction and evaporation of the liquid, which can then absorb heat from the die, and continue the cycle.

In an embodiment of the invention, the circuit boards 10 are made from LCP, which can be thermoformed around fluidic tubes 32 to ensure hermetic seals. However, any suitable sealing process or mechanism may be used to ensure fluid seals between the circuit boards 10, fluidic tubes 32 and fluidic pathways 33, as well as between the circuit boards 10 themselves. It is preferred that the directional arrangement of the microchannels 23 be parallel, or substantially parallel, to the flow of the fluid 34, and hence parallel to the directional arrangement of the fluidic pathways 33. Fluid 34 flowing through the cavity 19 thus also flows through the microchannels 23. The top surfaces 21 of the dies 20 are cooled by fluid 34 flowing within the cavity 19 between the dies 20 and the sidewall of the cavity 19, and the stacked die configuration is internally cooled by the flow of fluid 34 through the microchannels 23.

Each paired configuration 40 may itself serve as an embodiment liquid-cooled chip package with a stacked-die configuration. However, as shown in FIGS. 1 and 2, two or more paired configurations 40 can also be brought together to form an embodiment chip package 100 with greater than two bare IC dies 20. Each paired configuration 40 can be coupled to another paired configuration 40 using any suitable means to form the final chip package 100. For example, Z-axis electrically conductive adhesive 42, such as 9703 tape manufactured by the 3M Corporation, can be used to electrically and mechanically connect two paired configurations 40 together. The adhesive 42 mechanically binds the paired configurations 40 together, and is also electrically conductive along its Z axis but not along the X or Y axes. Hence, vertically aligned vias 12 can pass from one paired configuration 40 to another paired configuration 40 without shorting between non-aligned vias 12.

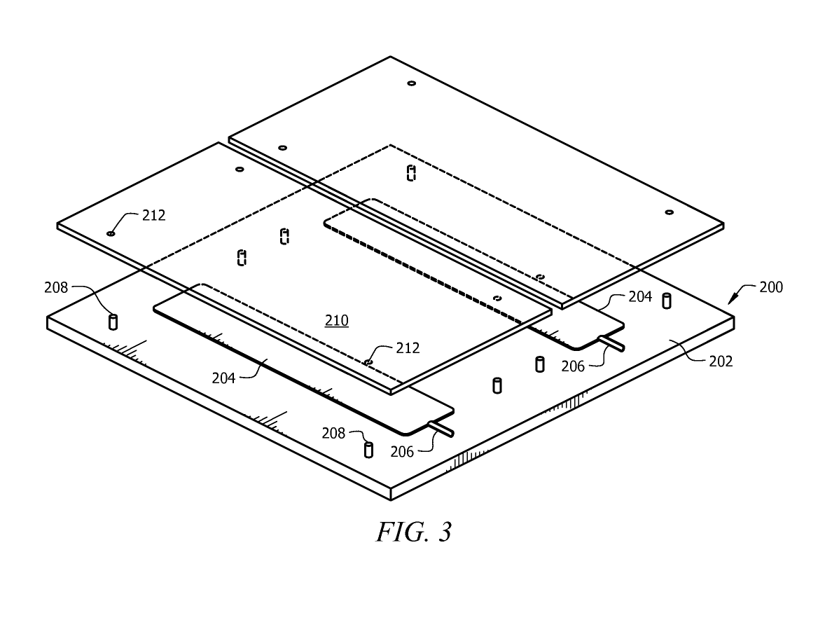

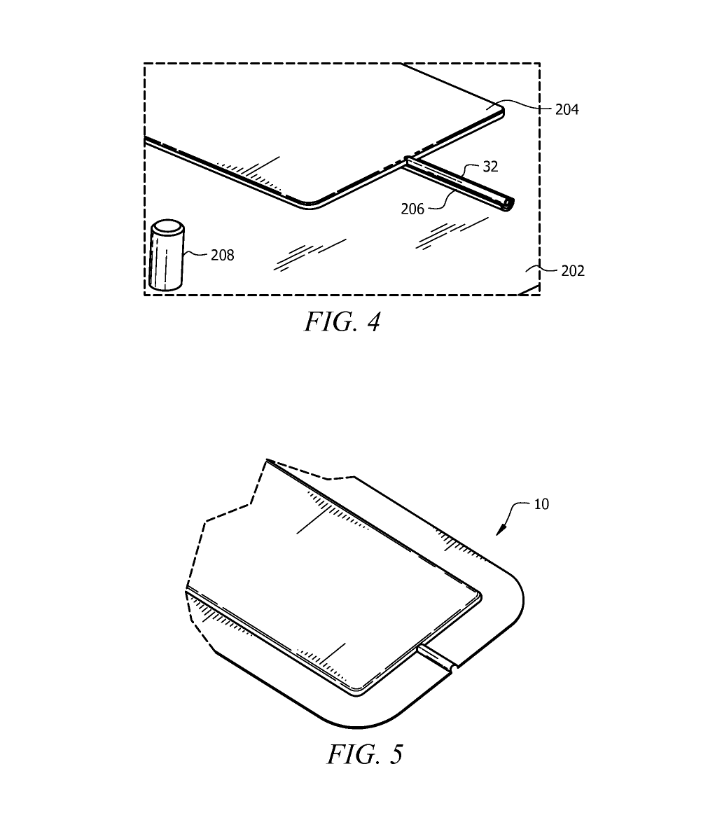

Please refer to FIGS. 3-5 in conjunction with FIGS. 1 and 2. To manufacture an embodiment chip package 100, it is desirable to provide a dimensionally formed circuit board 10 with a well or depression to form the cavity 19 when coupled to another flex circuit board 10. To this end, by way of example, a mold 200 can be provided that has the corresponding inverse shape desired of a dimensionally formed circuit board 10. The mold 200 can include a planar surface 202 with one or more protruding surfaces 204 that correspond to the desired cavities 19. The protruding surfaces 204 may be, for example, from 50 to 900 microns above the planar surface 202, preferably about 0.5 mm above the planar surface 202. Additionally, the mold 200 can include recesses 206 that partially accept respective fluidic tubes 32 or facsimiles thereof. Finally, the mold 200 can include alignment pins 208. The alignment pins 208 engage with corresponding holes 212 on a suitable substrate 210, such as a sheet of LCP.

By way of example, an unformed LCP sheet 210 is engaged with the mold 200, setting the alignment pins 208 through the holes 212 of the sheet 210. Additionally, a fluidic tube 32 or a suitable facsimile thereof is placed in the recess 206, protruding above the planar surface 202. The sheet 210 covers the protruding surface 204, and at least a portion of the tube 32 and the planar surface 202. The LCP sheet 210 can then be thermoformed into the desired shape using heat and pressure as known in the art, such as at 210-220° C. and 14.7 psig. When removed from the mold 200 a dimensionally formed circuit board 10 is provided. The LCP sheets are preferably fully fabricated with traces and vias prior to molding using conventional processes for substrate fabrication.

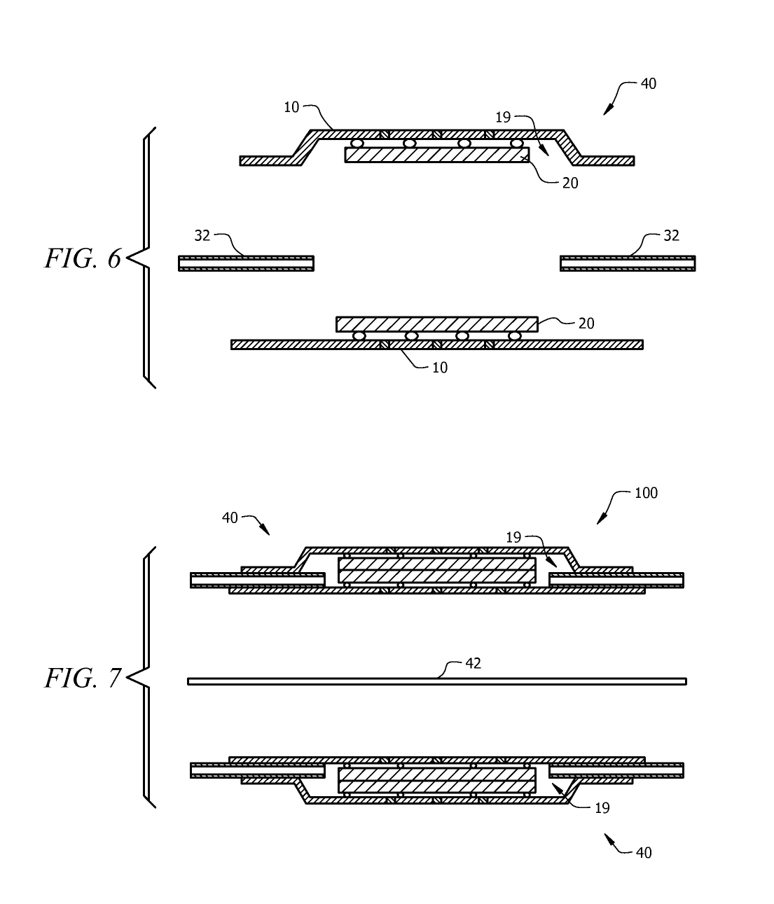

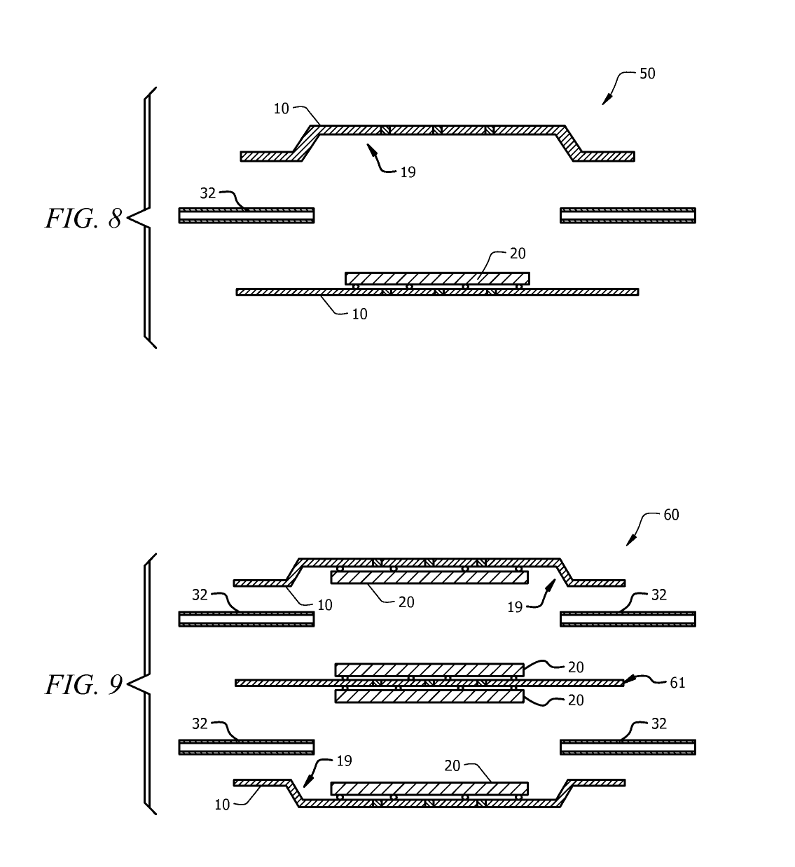

With further reference to FIGS. 6 and 7, after the circuit boards 10 have been dimensionally formed, the dies 20 can be attached to their respective circuit boards 10 at locations corresponding to the cavities 19 using conventional processes. In an exemplary embodiment, the attachment process can involve a flip chip die attachment method. With this method, the substrate is left in one half of the mold. The die is bumped with solder balls in a conventional manner. A pick-and-place machine would then place the die on the substrate pads. The substrate is heated to reflow the solder balls and form the electrical and structural connections. Still, the invention is not limited in this regard and other attachment methods are also possible. For example, the dies 20 can be attached to their respective circuit boards 10 using adhesive, epoxy, soldering, wire bonding or a combination of these methods. After the dies 20 have been attached in a suitable manner, the fluidic tubes 32 are positioned between respective pairs of circuit boards 10. As noted above, at least one of circuit boards 10 is dimensionally formed. The circuit boards 10 are then laminated together to form a paired configuration 40 with paired dies 20 disposed within the hermetic cavity 19 provided by one or more of the dimensionally formed circuit boards 10 in sealed conjunction with the other circuit board 10. Any suitable method can be used for the lamination process. For example, with reference to FIG. 8, the seal can be formed by applying a line of sealing adhesive such as Epo-Tek® H74 on one circuit board 10 around the perimeter of the cavity 19. After the circuit boards 10 are brought together, the adhesive is cured. Alternatively, a bond ply of LCP can be inserted between the top and bottom substrates 10. The bond ply material is similar to the material comprising the circuit boards 10 except that it has a lower melting point. An opening is cut in the bond ply so that it does not span the cavity 19. The bond ply bonds the two circuit boards 10 together when exposed to heat and pressure. For the case with stacked die as shown in FIG. 6, an adhesive such as THERM-A-FORM T644 from Chomerics may be applied between the die 20 to prevent relative motion. Following the lamination process, two or more paired configurations 40 shown in FIG. 7 can be brought together, using any suitable method, such as Z-axis electrically conductive adhesive 42, to form a finished package 100.

Variations on the above are certainly possible. For example, as shown in FIG. 8, a simpler, single die configuration 50 is possible. A single die 20 can be laminated between two circuit boards 10, one or more of which may be dimensionally formed so as to provide a suitable cavity 19 into which the die 20 is set and that is fluidly cooled via fluidic tubes 32, also sandwiched and sealed between the circuit boards 10. This single die configuration 50 can stand alone as a chip package, or can be combined with other configurations 40, 50 as discussed above to provide multi-die chip packages 100. Alternatively, more complex arrangements are possible. For example, a four-die configuration 60 is shown in FIG. 9. Dies 20 can be attached to both sides of a double-sided circuit board 61. This double-sided circuit board 61 can then be sandwiched between two dimensionally formed circuit boards 10, each providing a respective cavity 19, together with fluidic tubes 32 that feed the cavities 19. The entire stack can be laminated together to ensure that the cavities 19 are hermetically sealed to provide a fluidically-cooled, four-die configuration 60. As with the other embodiment configurations, the four-die configuration 60 can be used as a standalone chip package 100, or can be combined with one or more other configurations 40, 50, 60 to form a stacked die, fluidically cooled chip package. 100.

When constructing the configurations 40, 50, 60, the thermoforming of the layers, such as the circuit boards 10, 51 and the fluidic tubes 32, can leave gaps, particularly around the fluidic tubes 32. Consequently, in some embodiments it is desirable to use a sealant to fill such gaps. In an embodiment of the invention, the sealant can be an adhesive capable of forming a near hermetic seal. For example, an epoxy such as Epo-Tek (R) H74 can be used to seal around the tubes. The sealant can be applied around the tubes where they emerge from the circuit board substrate as the last step in the assembly process. A mild vacuum can be applied to the tubes to draw the sealant into any gaps. Alternatively, suitable temperature and pressure can be used during the lamination process so that the bond ply used to adhere the substrate layers together flows into the spaces around the tubes.

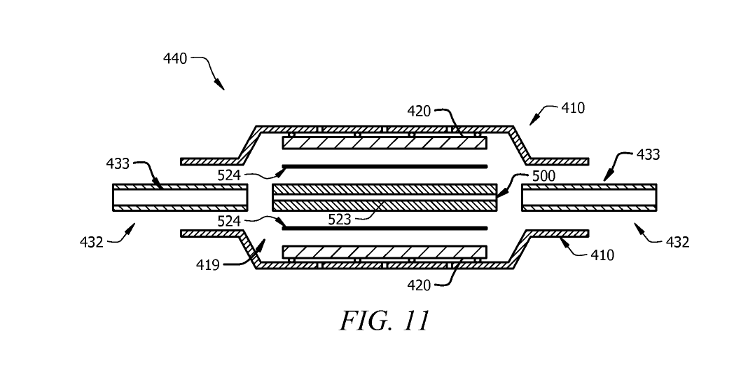

The invention has generally been described above in connection with bare IC dies, which do not have any packaging associated with them. However, the commercial industry might be more likely to use chip scale packaged (CSP) components instead of bare die ICs. As will be appreciated by those skilled in the art, CSP is a common industry term for packages that are no more than about 10% larger than the component being packaged. A single CSP can be arranged in a configuration similar to that described above with respect to FIG. 8. A paired configuration of CSPs is shown in FIG. 11, in which a first flex circuit board 410 with associated CSP 420 is brought together with a second flex circuit board 410 and its associated CSP 420. In some embodiments, a thermal enhancement spacer (TES) 500 is positioned between the two CSPs 420, although the invention is not limited in this regard and the TES can be optionally omitted. A front surface of each CSP 420 is mechanically and electrically connected to its respective flex circuit board 410 by way of solder 24, adhesive, wire bonding or the like.

The TES 500 has one or more fluid microchannels 523 which traverse the length of the TES and facilitate a flow of fluid therethrough. The direction of these fluid microchannels is advantageously aligned with the direction of fluid flow from one end of cavity 419 to an opposing end of cavity 419. Fluidic tubes 432 are disposed between the flex circuit boards 410. The fluidic tubes 432 provide fluidic pathways 433 that fluidically couple a cavity 419 (formed when the circuit boards 410 are joined together) with an external fluid source 5 (not shown in FIG. 11). The fluidic pathways 433 deliver fluid into the cavity 419 at one end and remove the fluid from the cavity 419 at an opposite end. If the TES 500 is used, then adhesive layers 524 can be provided to secure the TES to the CSPs, and provide a thermal transfer means. For example, the adhesive layers in such embodiments are advantageously selected to be thermally conductive adhesive layers. Thermally conductive adhesive layers are well known in the art. In other respects, the paired configuration of CSPs is similar to the arrangement described above for bare die ICs. Applicants present certain theoretical aspects above that are believed to be accurate that appear to explain observations made regarding embodiments of the invention. However, embodiments of the invention may be practiced without the theoretical aspects presented. Moreover, the theoretical aspects are presented with the understanding that Applicants do not seek to be bound by the theory presented.

While various embodiments of the present invention have been described above, it should be understood that they have been presented by way of example only, and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

Although the invention has been illustrated and described with respect to one or more implementations, equivalent alterations and modifications will occur to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

The terminology used herein is for the purpose of describing particular embodiments only and is not intended to be limiting of the invention. As used herein, the singular forms “a”, “an” and “the” are intended to include the plural forms as well, unless the context clearly indicates otherwise. Furthermore, to the extent that the terms “including”, “includes”, “having”, “has”, “with”, or variants thereof are used in either the detailed description and/or the claims, such terms are intended to be inclusive in a manner similar to the term “comprising.”

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

We claim:

1. A liquid cooled package for an integrated circuit die comprising:
at least two circuit boards coupled together, at least one of the at least two circuit boards dimensionally formed to define a first cavity;
an integrated circuit die disposed in the first cavity and electrically connected to at least one of the at least two circuit boards; and
a plurality of first fluidic pathways fluidically connected to the first cavity and configured for connecting to an external fluid source.

2. The liquid cooled package according to claim 1 wherein the at least two circuit boards are flex circuit boards that are laminated together.

3. The liquid cooled package according to claim 1 wherein two said integrated circuit dies are disposed in said first cavity, each mechanically coupled to a respective circuit board.

4. The liquid cooled package according to claim 3 wherein adjacent surfaces of the two integrated circuit dies comprise grooves, and the adjacent surfaces abut each other to form a stacked-die configuration with internal microchannels.

5. The liquid cooled package according to claim 4 wherein the microchannels are aligned with the first fluidic pathways.

6. The liquid cooled package according to claim 1 wherein the first fluidic pathways are formed by first fluidic tubes disposed between the at least two circuit boards.

7. The liquid cooled package according to claim 1 further comprising an electrical via that passes through at least one of the at least two circuit boards.

8. The liquid cooled package according to claim 7 further comprising another dimensionally formed circuit board coupled to the at least two circuit boards to define a second cavity, another integrated circuit die disposed within the second cavity, and a plurality of second fluidic pathways fluidically connected to the second cavity and configured for connecting to the external fluid source.

9. The liquid cooled package according to claim 8 wherein the electrical via is aligned with, and electrically coupled to, a corresponding electrical via in the another dimensionally formed circuit board.

10. The liquid cooled package according to claim 9 wherein the another dimensionally formed circuit board is electrically and mechanically coupled to one of the at least two circuit boards using an electrically conductive adhesive.

11. A packaging method for an integrated circuit die comprising:
dimensionally forming at least a first flex circuit board to create a cavity in association with a second flex circuit board;
mechanically coupling a first integrated circuit die to at least one of the first and second flex circuit boards at a position corresponding to the cavity; and
laminating together the first flex circuit board with at least the second flex circuit board to form the cavity and provide a plurality of fluidic pathways coupled to the cavity.

12. The packaging method according to claim 11 further comprising disposing fluidic tubes between the first and second flex circuit boards prior to laminating the first and second flex circuit boards together to form the fluidic pathways.

13. The packaging method according to claim 11 wherein said first integrated circuit die is mechanically coupled to the first flex circuit board, a second integrated circuit die is mechanically coupled to the second flex circuit board, and the first and second integrated circuit dies are disposed within the cavity.

14. The packaging method according to claim 13 further comprising:
laminating the first and second flex circuit boards together such that adjacent surfaces of the first and second integrated circuit dies abut each other within the cavity to form a stacked-die configuration.

15. The packaging method according to claim 14 wherein the adjacent surfaces comprise grooves to form microchannels within the stacked-die configuration.

16. The packaging method according to claim 11 further comprising disposing an electrically conductive adhesive on at least one of the first and second flex circuit boards and using the electrically conductive adhesive to mechanically and electrically couple to another flex circuit board.

17. A liquid cooled package for an integrated circuit die comprising:
at least two circuit boards coupled together, at least one of the at least two circuit boards dimensionally formed to define a first cavity;
a chip scale packaged integrated circuit disposed in the first cavity and electrically connected to at least one of the at least two circuit boards; and
a plurality of first fluidic pathways fluidically connected to the first cavity and configured for connecting to an external fluid source.

18. The liquid cooled package according to claim 17 wherein the at least two circuit boards are flex circuit boards that are laminated together.

19. The liquid cooled package according to claim 17 wherein two said chip scale packaged integrated circuits are disposed in said first cavity, each mechanically coupled to a respective circuit board.

20. The liquid cooled package according to claim 19 further comprising a thermal enhancement spacer disposed between opposing surfaces of the two chip scale packaged integrated circuits, said thermal enhancement spacer comprising a plurality of fluid channels.

21. The liquid cooled package according to claim 20, wherein said two chip scale packaged integrated circuits and said thermal enhancement spacer to form a stacked configuration, and further comprising an adhesive layer disposed between opposing surfaces of said thermal enhancement spacer and each of said chip scale packaged integrated circuits.
